(19) United States
(12) Patent Application Publication
(10) Pub. No.: US 2007/0148337 A1
(43) Pub. Date: Jun. 28, 2007

(54) Flame-perforated aperture masks

(76) Inventors: Jonathan A. Nichols, New Market, MN (US); Jeffrey H. Tokie, Scandia, MN (US); Michael W. Bench, Eagan, MN (US); Mark A. Strobel, Maplewood, MN (US); Joel A. Getschel, Osceola, WI (US); Donald J. McClure, Shoreview, MN (US)

Correspondence Address: 3M INNOVATIVE PROPERTIES COMPANY, PO BOX 33427, ST. PAUL, MN, 55133-3427, US

(21) Appl. No.: 11/315,111

(22) Filed: Dec. 22, 2005

(51) Int. Cl. H05K 3/00; B05D 3/08; B05D 1/32; C23C 16/00

(52) U.S. Cl. 427/98.4; 427/223; 427/282; 118/718; 118/720; 118/726

(57) ABSTRACT

An aperture mask is provided comprising an elongated web of flexible film having at least one deposition mask pattern formed in the film, wherein the deposition mask pattern defines deposition apertures that extend through the film that define at least a portion of one or more electronic circuit elements, and wherein deposition apertures are bounded by a rim, the rim being a portion of the mask which has a thickness greater than an average thickness for the mask. In another aspect, the present invention provides a method of making such an aperture mask comprising the steps of: providing a support surface, wherein the support surface includes a plurality of lowered portions; providing a burner, wherein the burner supports a flame, and wherein the flame includes a flame tip opposite the burner; contacting at least a portion of an elongated web of flexible film against the support surface; and heating the film with a flame from a burner to create apertures in the film in the areas covering the plurality of lowered portions.

### FIELD OF THE INVENTION

This invention relates to the manufacture of electronic circuit elements by the use of aperture masks made by a method of flame-perforation, the method of making those masks, and the aperture masks so made.

### BACKGROUND OF THE INVENTION

Electronic circuits include combinations of electronic circuit elements such as resistors, capacitors, inductors, diodes, transistors, and other active and passive components, linked together by electrically conductive connections. Thin film integrated circuits include a number of layers such as metal layers, dielectric layers, and active layers typically formed by a semiconductor material such as silicon. Typically, thin film circuit elements and thin film integrated circuits are created by depositing various layers of material and then patterning the layers using photolithography in an additive or subtractive process which can include a chemical etching step to define various circuit components. Additionally, aperture masks have been used to deposit a patterned layer without an etching step or any photolithography.

U.S. Pat. No. 6,821,348 B2 discloses certain methods and apparatus relating to aperture masks and related systems, and is incorporated herein by reference.

U.S. Pat. App. Pub. Nos. 2004/0070100 A1 and 2005/0073070 A1 disclose certain methods and apparatus relating to flame perforation of films, and are incorporated herein by reference.

U.S. patent application Ser. No. 11/179,418 discloses certain methods and apparatus relating to roll good aperture masks and related roll-to-roll or continuous motion systems, and is incorporated herein by reference.

### SUMMARY OF THE INVENTION

Briefly, the present invention provides an aperture mask comprising: an elongated web of flexible film; and at least one deposition mask pattern formed in the film, wherein the deposition mask pattern defines deposition apertures that extend through the film that define at least a portion of one or more electronic circuit elements, and wherein deposition apertures are bounded by a rim, the rim being a portion of the mask which has a thickness greater than an average thickness for the mask. The aperture mask may comprise a plurality of independent deposition mask patterns, which may be substantially the same or different. The web of film typically is sufficiently flexible such that it can be wound to form a roll. The web of film is typically stretchable in at least a down-web direction, a cross-web direction, or both. The web of film typically comprises a polymeric film, more typically a polyimide film or a polyester film. Typically at least one deposition aperture has a smallest diameter of less than approximately 1000 microns, more typically less than approximately 250 microns.

In another aspect, the present invention provides a method of making an aperture mask comprising an elongated web of flexible film; and a deposition mask pattern formed in the film, wherein the deposition mask pattern defines deposition apertures that extend through the film that define at least a portion of one or more electronic circuit elements. The method comprises the steps of: providing a support surface, wherein the support surface includes a plurality of lowered portions; providing a burner, wherein the burner supports a flame, and wherein the flame includes a flame tip opposite the burner; contacting at least a portion of an elongated web of flexible film against the support surface; and heating the film with a flame from a burner to create apertures in the film in the areas covering the plurality of lowered portions. In one embodiment, the support surface is cooled to a temperature lower than 120° F. (29° C.); and the first side of the film is contacted with a heated surface, wherein the heated surface is greater than 165° F. (74° C.); and subsequently the heated surface is removed from the first side of the film prior to heating the film with a flame from a burner to create apertures in the film in the areas covering the plurality of lowered portions. Another embodiment additionally comprises the step of positioning the burner such that the distance between an unimpinged flame tip of the flame and the burner is at least one-third greater than the distance between the film and the burner. The positioning step may additionally include positioning the burner such that the distance between the unimpinged flame tip of the flame and the burner is at least 2 millimeters greater than the distance between the film and the burner. Another embodiment additionally comprises the step of positioning the burner such that the angle measured between the burner and the nip roll is less than 45°, wherein a vertex of the angle is positioned at an axis of the backing roll.

In another aspect, the present invention provides a method of making an electronic circuit element, comprising the steps of: providing a support surface, wherein the support surface includes a plurality of lowered portions; providing a burner, wherein the burner supports a flame, and wherein the flame includes a flame tip opposite the burner; contacting at least a portion of an elongated web of flexible film against the support surface; heating the film with a flame from a burner to create apertures in the film in the areas covering the plurality of lowered portions, thereby making an aperture mask; providing a first web of film; positioning the aperture mask and first web of film in proximity to each other; and depositing a deposition material on the first web of film through the apertures in the aperture mask to create at least a portion of one or more electronic circuit elements. In one embodiment, the method additionally comprises the step of recovering deposition material accumulated on the aperture mask by a method which precludes reuse of the aperture mask, which may optionally include partially or wholly burning the aperture mask, partially or wholly melting the aperture mask, partially or wholly dividing the aperture mask into pieces, and partially or wholly dissolving the aperture mask.

### BRIEF DESCRIPTION OF THE DRAWING

FIG. 1 is a perspective view of an aperture mask in the form of an aperture mask web wound into a roll.

FIG. 2a is a top view of an aperture mask according to an embodiment of the invention.

FIG. 2b is an enlarged view of a portion of the aperture mask in FIG. 2a.

FIG. 2c is an enlarged view of a single aperture of the aperture mask in FIG. 2a.

FIG. 2d is a cross section of the aperture of FIG. 2c.

FIGS. 3-5 are top views of aperture masks according to embodiments of the invention.

FIG. 6 is a side view of a flame-perforating apparatus useful in the method of the present invention.

FIG. 7 is a front view of the apparatus of FIG. 6 with two of the idler rolls and motor removed for clarity, and the backing roll shown in phantom lines.

FIG. 7a is an enlarged view of the ribbons of the burner of the apparatus of FIG. 6.

FIG. 8 is a side view of the apparatus of FIG. 6 including film moving along the film path within the apparatus.

FIG. 9 is an enlarged cross-sectional view of portions of the burner, film, and backing roll with a flame of the burner positioned away from the film, such that the flame is an unimpinged flame.

FIG. 10 is a view like FIG. 9 with the flame of the burner impinging the film.

FIGS. 11 and 12 are simplified illustrations of in-line aperture mask deposition techniques.

FIGS. 13 and 14 are block diagrams of deposition stations according to the invention.

FIG. 15a is a perspective view of one exemplary stretching apparatus according to an embodiment of the invention.

FIG. 15b is an enlarged view of a stretching mechanism.

FIGS. 16-18 are top views of exemplary stretching apparatuses according to embodiments of the invention.

FIG. 19 is a block diagram of an exemplary in-line deposition system according to an embodiment of the invention.

FIGS. 20 and 21 are cross-sectional views of exemplary thin film transistors that can be created according to the invention.

### DETAILED DESCRIPTION

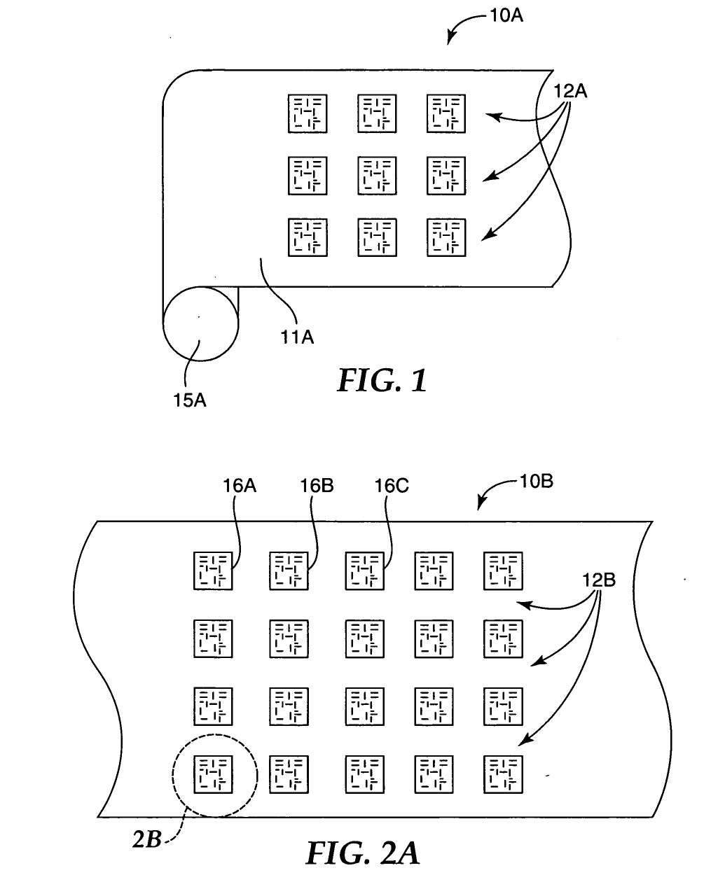

FIG. 1 is a perspective view of an aperture mask 10A. As shown, aperture mask 10A includes an elongated web of flexible film 11A, and a deposition mask pattern 12A formed in the film. The deposition mask pattern 12A defines deposition apertures (not labeled in FIG. 1) that extend through the film. Typically, aperture mask 10A is formed with a number of deposition mask patterns, although the invention is not necessarily limited in that respect. In that case, each deposition mask pattern may be substantially the same, or alternatively, two or more different mask patterns may be formed in flexible film 11A.

As shown, flexible film 11A may be sufficiently flexible such that it can be wound to form a roll 15A. The ability to wind flexible film 11A onto a roll provides a distinct advantage in that the roll of film 15A has a substantially compact size for storage, shipping and use in an inline deposition station. Also, flexible film 11A may be stretchable such that it can be stretched to achieve precise alignment. For example, the flexible film may be stretchable in a cross-web direction, a down-web direction, or both. In exemplary embodiments, flexible film 11A may comprise a polymeric film. The polymeric film may be comprised of one or more of a wide variety of polymers including polyimide, polyester, polystyrene, polymethyl methacrylate, polycarbonate, or other polymers. Polyimide is a particularly useful polymer for flexible film 11A. Polyester is also a particularly useful polymer for flexible film 11A. Preferably, the film 70 a polymeric substrate.

Aperture mask 10A is subject to a wide variety of shapes and sizes. For example, in exemplary embodiments, a web of flexible film 11A is at least approximately 50 centimeters in length or 100 centimeters in length, and in many cases, may be at least approximately 10 meters, or even 100 meters in length. Also, the web of flexible film 11A may be at least approximately 3 cm in width, and less than approximately 200 microns in thickness, less than approximately 30 microns, or even less than approximately 10 microns in thickness.

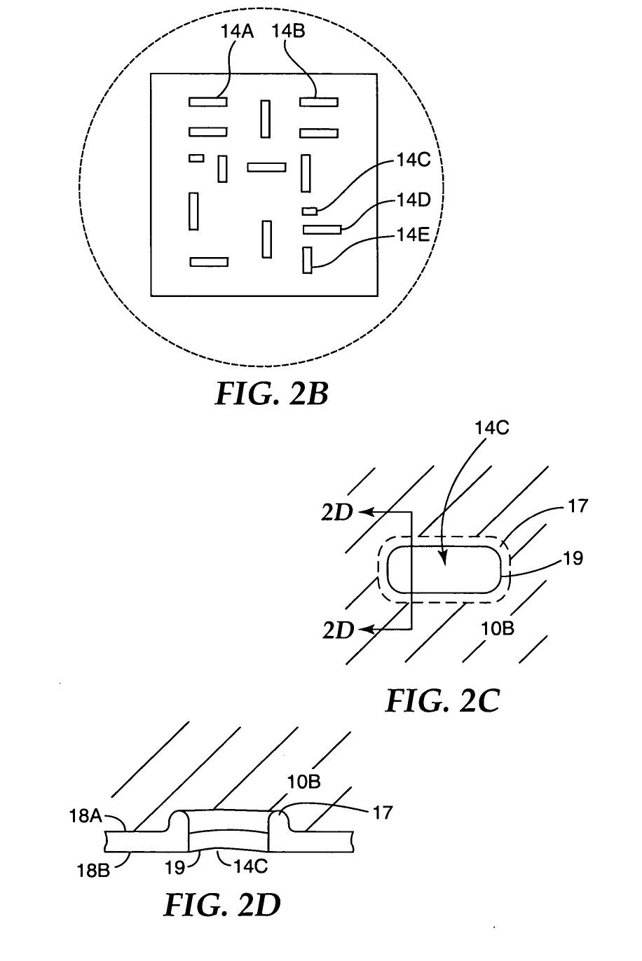

FIG. 2a is a top view of a portion of an aperture mask 10B according to the invention. In exemplary embodiments, aperture mask 10B as shown in FIG. 2a is formed from a polymer material. The use of polymeric materials for aperture mask 10B can provide advantages over other materials, including ease of fabrication of aperture mask 10B, reduced cost of aperture mask 10B, and other advantages. As compared to thin metal aperture masks, polymer aperture masks are much less prone to damage due to accidental formation of creases and permanent bends. Furthermore, some polymer masks can be cleaned with acids.

As shown in FIGS. 2a and 2b, aperture mask 10B is formed with a pattern 12B that defines a number of deposition apertures 14 (only deposition apertures 14A-14E are labeled). The arrangement and shapes of deposition apertures 14A-14E in FIG. 2b are simplified for purposes of illustration, and are subject to wide variation according to the application and circuit layout envisioned by the user. Pattern 12B defines at least a portion of a circuit layer and may generally take any of a number of different forms. In other words, deposition apertures 14 can form any pattern, depending upon the desired circuit elements or circuit layer to be created in the deposition process using aperture mask 10B. For example, although pattern 12B is illustrated as including a number of similar sub-patterns (sub-patterns 16A-16C are labeled), the invention is not limited in that respect.

FIG. 2c is a top view of a single deposition aperture 14C in a mask 10B according to the invention. FIG. 2d is cross section of deposition aperture 14C in mask 10B according to the invention. Deposition aperture 14F is bounded by rim 17. Rim 17 is a portion of mask 10B which has an increased thickness, typically a thickness greater than the average thickness of mask 10B. In the embodiment shown in FIGS. 2c and 2d, one surface 18B of mask 10B remains substantially planar as it approaches the edge 19 of deposition aperture 14F while another surface 18A of the mask 10B rises as it approaches the edge 19 of deposition aperture 14F, thereby creating rim 17. In an alternate embodiment, not shown, neither surface of the mask remains substantially planar as it approaches the edge of a deposition aperture.

Aperture mask 10B can be used in a deposition process, such as a vapor deposition process in which material is deposited onto a deposition substrate through deposition apertures 14 to define at least a portion of a circuit. Advantageously, aperture mask 10B enables deposition of a desired material and, simultaneously, formation of the material in a desired pattern. Accordingly, there is no need for a separate patterning step following or preceding deposition. Aperture mask 10B may be used to create a wide variety of electronic circuits, including integrated circuits, such as integrated circuits which include a complimentary (both n-channel and p-channel) transistor element. In addition, organic (e.g., pentacene) or inorganic (e.g., amorphous silicon) semiconductor materials may be used to create integrated circuits according to the invention. In some embodiments, Aperture mask 10B may be used to create organic LED's (OLED's). For some circuits, both organic and inorganic semiconductors may be used.

Aperture mask 10B can be particularly useful in creating circuits for electronic displays such as liquid crystal displays or organic light emitting displays, low-cost integrated circuits such as RFID circuits, or any circuit that implements thin film transistors. Moreover, circuits that make use of organic semiconductors can benefit from various aspects of the invention as described in greater detail below. In addition, because aperture mask 10B can be formed out of a flexible web of polymeric material, it can be used in an in-line process as described in greater detail below.

One or more deposition apertures 14 can be formed to have widths less than approximately 1000 microns, less than approximately 500 microns, less than approximately 250 microns, or even less than approximately 200 microns. By forming deposition apertures 14 to have widths in these ranges, the sizes of the circuit elements may be reduced. Moreover, a distance (gap) between two deposition apertures (such as for example the distance between deposition aperture 14C and 14D) may be less than approximately 1000 microns, less than approximately 500 microns, less than approximately 250 microns, or even less than approximately 200 microns, to reduce the size of various circuit elements.

Formation of aperture mask 10B from a web of polymeric film can allow the use of fabrication processes that can be less expensive, less complicated, and/or more precise than those generally required for other aperture masks such as silicon masks or metallic masks. These large masks can then be used in a deposition process to create circuit elements that are distributed over a large surface area and separated by large distances. Moreover, by forming the mask on a large polymeric web, the creation of large integrated circuits can be done in an in-line process.

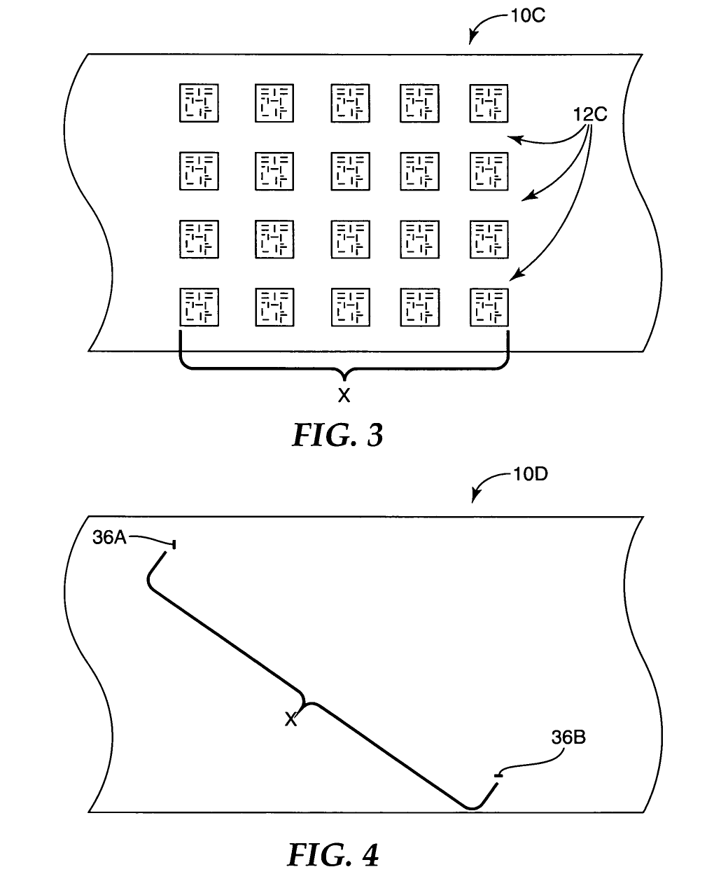

FIGS. 3 and 4 are top views of aperture masks 10C and 10D that include deposition apertures separated by relatively large widths. Still, aperture masks 10C and 10D are formed out of a web of film to allow the deposition processes to be conducted in-line. FIG. 3 illustrates aperture mask 10C, which includes a pattern 12C of deposition apertures. Pattern 12C may define at least one dimension that is greater than approximately a centimeter, greater than approximately 25 centimeters, greater than approximately 100 centimeters, or even greater than approximately 500 centimeters. In other words, the distance X may be within those ranges. In this manner, circuit elements separated by larger than conventional distances can be created using a deposition process. This feature may be advantageous, for example, in the fabrication of large area flat panel displays or detectors.

For some circuit layers, complex patterns may not be required. For example, aperture mask 10D of FIG. 4 includes at least two deposition apertures 36A and 36B. In that case, the two deposition apertures 36A and 36B can be separated by a distance X that is greater than approximately a centimeter, 25 centimeters, 100 centimeters, or even greater than approximately 500 centimeters. The ability to deposit and pattern a circuit layer in a single deposition process with elements separated by these large distances can be highly advantageous for creating circuits that require large separation between two or more elements. Circuits for controlling or forming pixels of large electronic displays are one example.

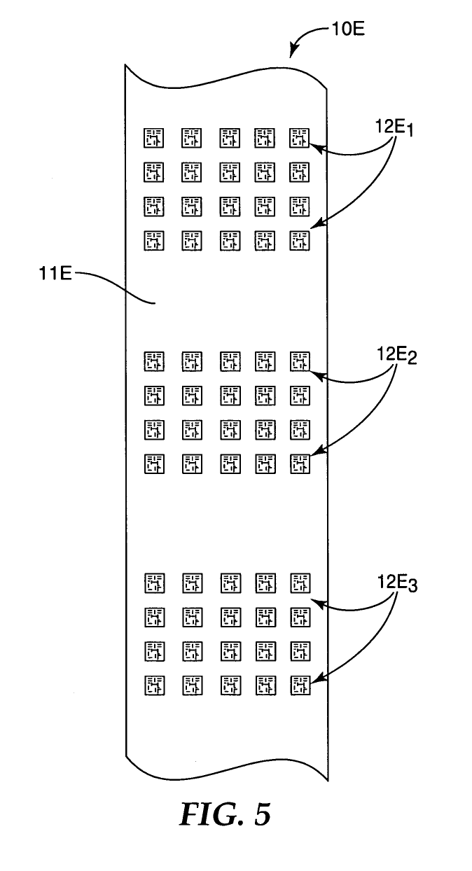

FIG. 5 is a top view of aperture mask 10E. As shown, aperture mask 10E is formed in a web of flexible material 11E, such as a polymeric material. Aperture mask 10E defines a number of patterns 12E₁-12E₃. In some cases, the different patterns 12E may define different layers of a circuit, and in other cases, the different patterns 12E define different portions of the same circuit layer. In some cases, stitching techniques can be used in which first and second patterns 12E₁ and 12E₂ define different portions of the same circuit feature. In other words, two or more patterns may be used for separate depositions to define a single circuit feature. Stitching techniques can be used, for example, to avoid relatively long deposition apertures, closed curves, or any aperture pattern that would cause a portion of the aperture mask to be poorly supported, or not supported at all. In a first deposition, one mask pattern forms part of a feature, and in a second deposition, another mask pattern forms the remainder of the feature.

In still other cases, the different patterns 12E may be substantially the same. In that case, each of the different patterns 12E may be used to create substantially similar deposition layers for different circuits. For example, in an in-line web process, a web of deposition substrates may pass perpendicular to aperture mask 10E. After each deposition, the web of deposition substrates may move in-line for the next deposition. Thus, pattern 12E₁ can be used to deposit a layer on the web of deposition substrates, and then 12E₂ can be used in a similar deposition process further down the web of deposition substrates. Each portion of aperture mask 10E containing a pattern may also be reused on a different portion of the deposition substrate or on one or more different deposition substrates. More details of an in-line deposition system are described below.

The aperture mask of the present disclosure may be made by any suitable method, including molding and perforating methods. Typically, the aperture mask of the present disclosure is made by a method of flame perforation.

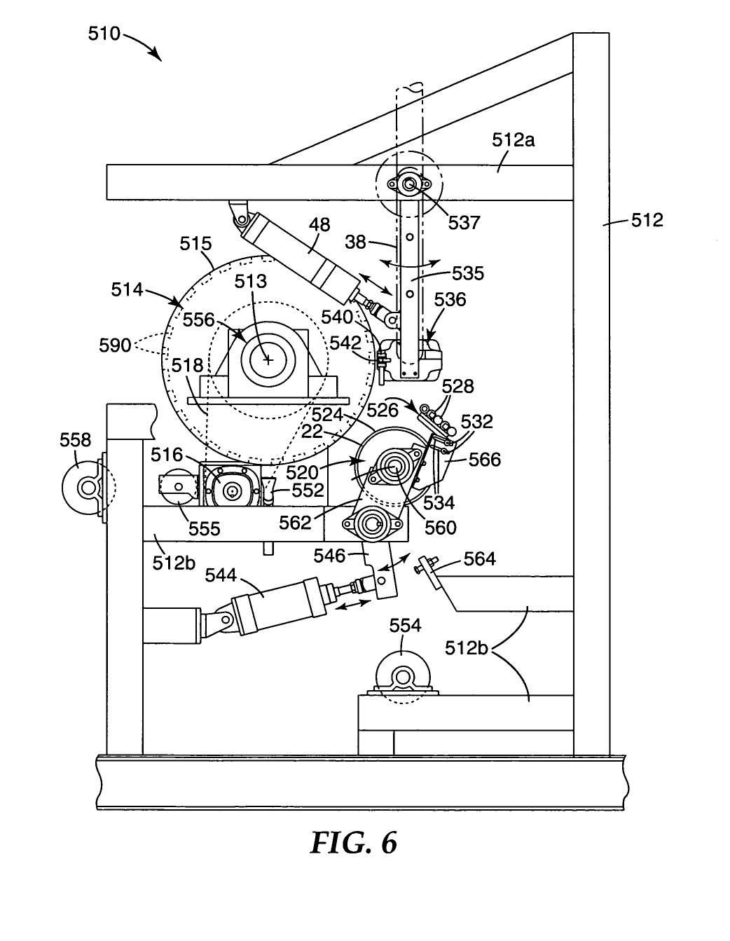

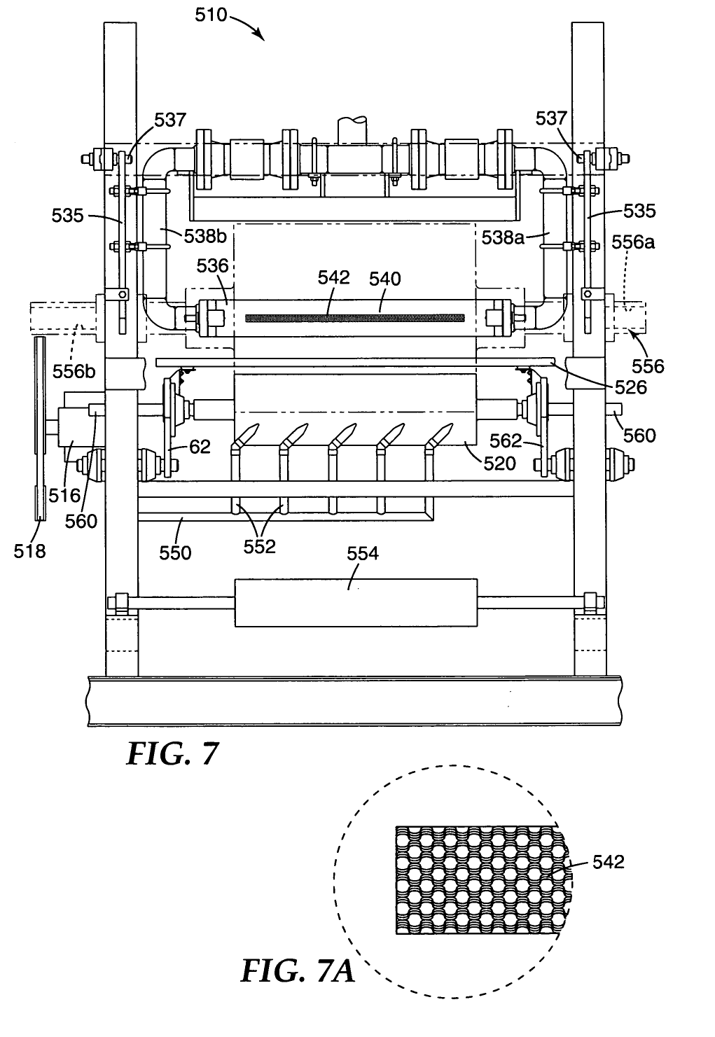

FIGS. 6 and 7 are illustrations of one apparatus for making flame-perforated aperture masks of the present disclosure. FIG. 6 illustrates a side view of the apparatus 510. FIG. 7 illustrates a front view of the apparatus with the backing roll 514 shown in phantom lines, and with the idler rollers 555, 558 and motor 516 removed, for clarity.

The apparatus 510 includes a frame 512. The frame 512 includes an upper portion 512a and a lower portion 512b. The apparatus 510 includes a backing roll 514 having an outer support surface 515. The support surface 515 preferably includes a pattern of lowered portions 590, shown in phantom lines. These lowered portions 590 and the portions of the support surface 515 between the lowered portions 590 collectively make up the support surface 515 of the backing roll 514. The lowered portions 90 form a pattern of indentions in the support surface 515. The lowered portions 590 may be a plurality of depressed or recessed portions or a plurality of indentations along the support surface 515. These lowered portions 590 are preferably etched into the support surface 515. Alternatively, the pattern of lowered portions 590 may be drilled, ablated, or engraved into the support surface 515. The pattern of the lowered portions 590 is a pattern that defines at least a portion of one or more electronic circuit elements, or at least a portion of one or more electronic circuits, or at least a portion of one or more integrated circuits.

Preferably, the support surface 515 of the backing roll 514 is temperature-controlled, relative to the ambient temperature around the apparatus 510. The support surface 515 of the backing roll 514 may be temperature-controlled by any suitable method known in the art. Preferably, the support surface 515 of the backing roll 514 is cooled by providing cooled water into the inlet portion 556a of hollow shaft 556, into the backing roll 514, and out of the outlet portion 556b of the hollow shaft 556. The backing roll 514 rotates about its axis 513. The apparatus 510 includes a motor 516 attached to the lower portion 512b of the frame. The motor drives a belt 518, which in turn rotates the shaft 556 attached to the backing roll 514, thus driving the backing roll 514 about its axis 513.

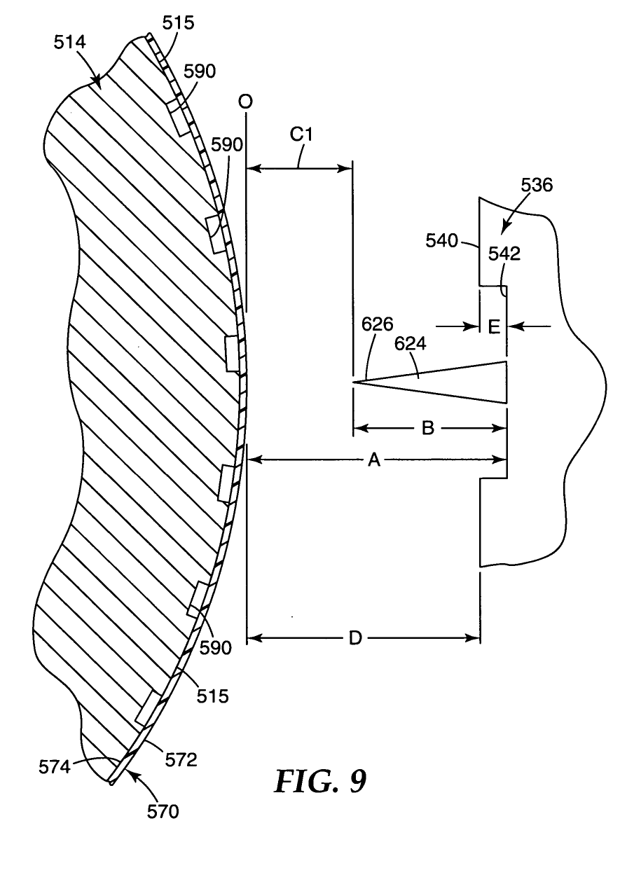

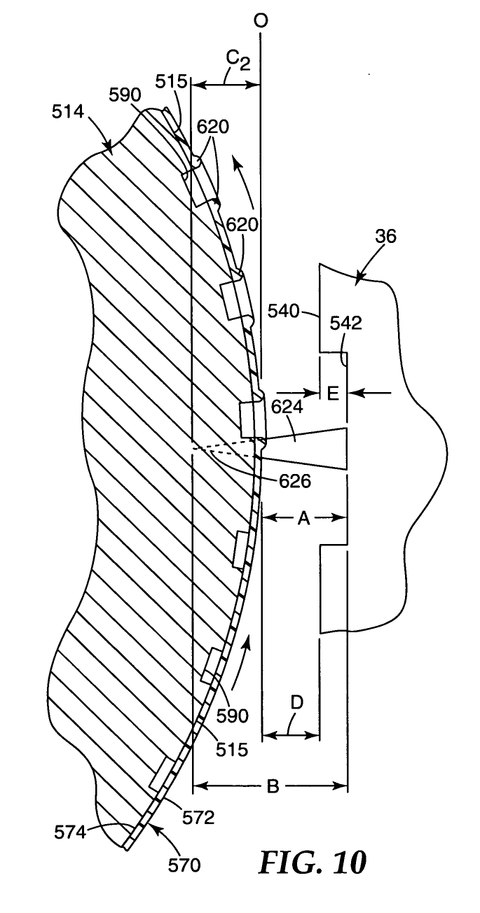

The apparatus 510 includes a burner 536 and its associated piping 538. The burner 536 and burner piping 538 are attached to the upper portion 512a of the frame 512 by burner supports 535. The burner supports 535 may pivot about pivot points 537 by actuator 548 to move the burner 536 relative to the support surface 515 of the backing roll 514. The supports 535 may be pivoted by the actuator 548 to position the burner 536 a desired distance either adjacent or away from the support surface 515 of backing roll 514, as explained in more detail with respect to FIGS. 9 and 10 below. The burner 536 includes a gas pipe 538 on each end for providing gas to the burner 536. The apparatus 510 may include an optional exhaust hood (not shown) mounted above the apparatus 510.

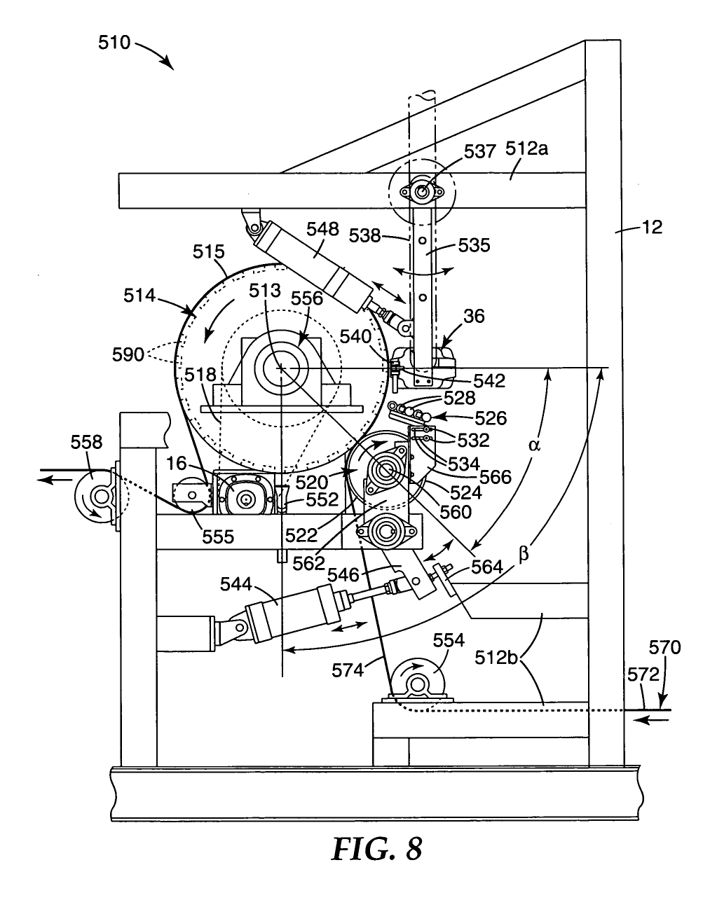

In one embodiment of the present invention, the apparatus 510 includes a preheat roll 520 attached to the lower portion 512b of the frame 512. The preheat roll 520 includes an outer roll layer 522. The outer roll layer 522 includes an outer surface 524. Preferably, the outer roll layer is made of an elastomer, preferably a high-service-temperature elastomer. Preferably, the preheat roll 520 is a nip roll, which may be positioned against the backing roll 514 to nip the film between the nip roll 520 and backing roll 514. However, it is not necessary that the preheat roll 520 be a nip roll and instead, the preheat roll may be positioned away from the backing roll 514 so as to not contact the backing roll 514. The nip roll 520 freely rotates about its shaft 560 and is mounted to roll supports 562. Linkage 546 is attached to roll supports 562. The nip roll 520 may be positioned against the backing roll 514, using actuator 544. When the actuator 544 is extended (as shown in FIG. 8), the linkage 546 is rotated counterclockwise, and in turn, the roll supports 562 are rotated counterclockwise until the nip roll 520 contacts the backing roll 514. The actuator 544 may control the movement between the nip roll 520 and the backing roll 514, and thus may control the pressure between the nip roll 520 and backing roll 514. A stop 564 is attached to the lower frame 512b to inhibit the movement of the linkage 546 beyond the lower frame 512b, which help limit the pressure applied by the nip roll 520 against the backing roll 514.

In another embodiment of the present invention, the apparatus 510 includes a temperature-controlled shield 526 attached to the nip roll 520 by brackets 566 to form one assembly. Accordingly, when the actuator 544 rotates the nip roll 520, as explained above, the shield 526 moves with the nip roll. The shield 526 may be positioned relative to the nip roll 520 by bolts 532 and slots 534 attached to the brackets 566. The temperature-controlled shield 526 preferably includes a plurality of water-cooled pipes 528. However, other means of providing a temperature-controlled shield may be used, such as water-cooled plate, air-cooled plate, or other means in the art. Preferably, the temperature-controlled shield 526 is positioned between the burner 536 and the nip roll 520. In this position, the shield 526 protects the nip roll 520 from some of the heat generated from the burner 536, and thus, can be used to control the temperature of the outer surface 524 of the nip roll 520, which has the benefits of reducing wrinkles or other defects in the film at the flame-perforation step performed by the burner 536, while maintaining high film speeds.

In yet another embodiment of the present invention, the apparatus 510 includes an optional applicator 550 attached to the lower portion 512b of frame 512. The apparatus 510 includes a plurality of nozzles 552. In one embodiment, the applicator 550 is an air applicator for applying air onto the backing roll 514. In another embodiment, the applicator 550 is a liquid applicator for applying liquid onto the backing roll 514. Preferably, the liquid is water, however other liquids may be used instead. If the liquid is applied by the applicator 550, then preferably, air is also supplied to the individual nozzles to atomize the liquid prior to application on the backing roll. The manner in which the air or water may be applied to the backing roll 514 may be varied by one skilled in the art, depending on the pressure, rate or velocity of the air or water pumped through the nozzles 552. As explained below, without wishing to be bound by any theory, it is believed that if air or water is applied to the support surface 515 of the backing roll 514, prior to contacting the film to the support surface 515, then this application of air or water helps either remove some of the condensation built up on the support surface 515 or applies additional water to actively control the amount of water between the film and the support surface, and thereby helps in eliminating wrinkles or other defects formed in the film at the flame-perforation step conducted by the burner 536.

The apparatus 510 includes a first idle roller 554, a second idle roller 555, and a third idle roller 558 attached to the lower portion 512b of the frame 512. Each idle roller 554, 555, 558 includes their own shafts and the idle rollers may freely rotate about their shafts.

FIG. 7a illustrates a blown-up view of the burner 536 useful with the apparatus 510 of FIG. 1. A variety of burners 536 are commercial available, for example, from Flynn Burner Corporation, New Rochelle, N.Y.; Aerogen Company, Ltd., Alton, United Kingdom, and Sherman Treaters Ltd., Thame, United Kingdom. One preferred burner is commercially available from Flynn Burner Corporation as Series 850, which has an eight-port, 32 inch actual length that was deckled to 27 inch in length, stainless steel, deckled ribbon mounted in a cast iron housing. A ribbon burner is most preferred for the flame perforation of polymer films, but other types of burners such as drilled-port or slot design burners may also be used. Preferably, the apparatus includes a mixer to combine the oxidizer and fuel before it feeds the flame used in the flame-perforating process of the invention.

FIG. 8 illustrates the path that the film travels through the apparatus 510 and one typical method of flame-perforating films. The film 570 includes a first side 572 and a second side 574 opposite the first side 572. The film travels into apparatus 510 and around first idle roller 554. From there, the film is pulled by the motor-driven backing roll 514. In this position, the film is positioned between the nip roll 520 and the backing roll 514. In this step of the process, the second side 574 of the film 570 is cooled by the water-chilled backing roll 514 and the first side 572 of the film 570 is simultaneously heated by the outer surface 524 of the pre-heat or nip roll 520. This step of preheating the film 570 with the nip roll surface 522 of the nip roll 520 prior to flame-perforating the film with the burner 536 provides the benefits of reducing wrinkling or other defects in the film after the flame-perforation step is performed by the burner 536.

The temperature of the outer support surface 515 of the backing roll 514 may be controlled by the temperature of the water flowing through the backing roll 514 through shaft 556. The temperature of the outer support surface 515 may vary depending on its proximity to the burner 536, which generates a large amount of heat from its flames. In addition, the temperature of the support surface 515 will depend on the material of the support surface 515.

The temperature of the outer surface 524 of the outer layer 522 of the nip roll 520 is controlled by a number of factors. First, the temperature of the flames of the burner affects the outer surface 524 of the nip roll 520. Second, the distance between the burner 536 and the nip roll 520 affects the temperature of the outer surface 524. For example, positioning the nip roll 520 closer to the burner 536 will increase the temperature of the outer surface 524 of the nip roll 520. Conversely, positioning the nip roll farther away from the burner 536 will decrease the temperature of the outer surface 524 of the nip roll 520. The distance between the axis of nip roll 520 and the center of the burner face 540 of the burner 536, using the axis 513 of the backing roll 514 as the vertex of the angle, is represented by angle alpha (α). Angle alpha (α) represents the portion of the circumference of the backing roll or the portion of the arc of the backing roll between the nip roll 520 and the burner 536. It is preferred to make angle alpha (α) as small as possible, without subjecting the nip roll to such heat from the burner that the material on the outer surface of the nip roll starts to degrade. For example, angle alpha (α) is preferably less than or equal to 45°. Third, the temperature of the outer surface 524 of the nip roll 520 may also be controlled by adjusting the location of the temperature-controlled shield 526 between the nip roll 520 and the burner 536, using bolts 532 and slots 534 of the brackets 566. Fourth, the nip roll 520 may have cooled water flowing through the nip roll, similar to the backing roll 514 described above. In this embodiment, the temperature of water flowing through the nip roll may affect the surface temperature of the outer surface 524 of the nip roll 520. Fifth, the surface temperature of the support surface 515 of the backing roll 514 may affect the surface temperature of the outer surface 524 of the nip roll 520. Lastly, the temperature of the outer surface 524 of the nip roll 520 may also by impacted by the ambient temperature of the air surrounding the nip roll 520.

Preferred temperatures of the support surface 515 of backing roll 514 are in the range of 45° F. to 130° F., and more preferably are in the range of 50° F. to 105° F. Preferred temperatures of the nip roll surface 524 of nip roll 520 are in the range of 165° F. to 400° F., and more preferably are in the range of 180° F. to 250° F. However, the nip roll surface 524 should not rise above the temperature at which the nip roll surface material may start to melt or degrade. Although the preferred temperatures of the support surface 515 of the backing roll 514 and the preferred temperatures of the nip roll surface 524 of the nip roll 520 are listed above, one skilled in the art, based on the benefits of the teaching of this application, could select preferred temperatures of the support surface 515 and nip roll surface 524 depending on the film material and the rotational speed of the backing roll 514 to flame-perforate film with reduced numbers of wrinkles or defects.

Returning to the process step, at this location between the preheat roll 520 and backing roll 514, the preheat roll preheats the first side 572 of the film 570 prior to contacting the film with the flame of the burner.

In the next step of the process, the backing roll 514 continues to rotate moving the film 570 between the burner 536 and the backing roll 514. This particular step is also illustrated in FIG. 10, as well as FIG. 8. When the film comes in contact with the flames of the burner 536, the portions of the film that are directly supported by the chilled metal support surface are not perforated because the heat of the flame passes through the film material and is immediately conducted away from the film by the cold metal of the backing roll 514, due to the excellent heat conductivity of the metal. However, a pocket of air is trapped behind those portions of the film material that are covering the etched indentations or lowered portions 590 of the chilled support material. The heat conductivity of the air trapped in the indentation is much less than that of the surrounding metal and consequently the heat is not conducted away from the film. The portions of film that lie over the indentations then melt and are perforated. As a result, the perforations formed in the film 570 correlate generally to the shape of the lowered portions 590. At about the same time that film material is melted in the areas of the lowered portions 590, a rim 620 is formed around each perforation, which consists of the film material from the interior of the perforation that has contracted upon heating.

After the burner 536 has flame-perforated the film, the backing roll 514 continues to rotate, until the film 570 is eventually pulled away from the support surface 515 of the backing roll 514 by the idler roller 555. From there, the flame-perforated film 570 is pulled around idler roll 558 by another driven roller (not shown). The flame-perforated film may be produced by the apparatus 510 in long, wide webs that can be wound up as rolls for convenient storage and shipment.

As mentioned above, the apparatus 510 may include the optional applicator 550 for either applying air or water to the support surface 515 of the backing roll 514, prior to the film 570 contacting the support surface between the backing roll 514 and the nip roll 520. Without wishing to be bound by any theory, it is believed that controlling the amount of water between the film 570 and the support surface 515 helps reduce the amount of wrinkles or other defects in the flame-perforated film. There are two ways in which to control the amount of water between the film 570 and the support surface 515. First, if the applicator 550 blows air onto the support surface, then this action helps reduce the amount of water build up between the film 570 and support surface 515. The water build up is a result of the condensation that is formed on the backing roll surface when the water-cooled support surface 515 is in contact with the surrounding environment. Second, the applicator 550 may apply water or some other liquid to the support surface 515 to increase the amount of liquid between the film 570 and the support surface. Either way, it is believed that some amount of liquid between the film 570 and the support surface 515 may help increase the traction between the film 570 and the support surface 515, which in turn helps reduce the amount of wrinkles or other defects in the flame-perforated film. The position of the nozzles 552 of the applicator 550 relative to the centerline of the burner 536 is represented by angle beta (β), where the vertex of the angle is at the axis of the backing roll 514. Preferably, the applicator 550 is at an angle beta (β) which is greater than angle alpha (α), so that the air or water is applied to the backing roll 514 prior to the nip roll 520.

FIGS. 9 and 10 schematically illustrate yet another embodiment of the apparatus of the present invention. FIGS. 9 and 10 illustrate the criticality of the placement of the flame 624 relative to the support surface 515 of the backing roll 514 during the flame-perforation step. In FIG. 9, the burner 536 is at some distance relative to the backing roll 514, and in FIG. 10, the burner 536 is positioned closer to the backing roll 514 relative to FIG. 4. The relative distance between the burner 536 and backing roll 514 may be adjusted by the burner supports 535 and the actuator 548, as explained above in reference to FIG. 1.

There are several distances represented by reference letters in FIGS. 4 and 5. Origin “O” is measured at a tangent line relative to the first side 572 of the film wrapped around the backing roll 514. Distance “A” represents the distance between the ribbons 542 of the burner 540 and the first side 572 of the film 570. Distance “B” represents the length of the flame, as measured from the ribbons 542 of the burner 536, where the flame originates, to the tip 626 of the flame. The flame is a luminous cone supported by the burner, which can be measured from origin to tip with means known in the art. Actually, the ribbon burner 536 has a plurality of flames and preferably, all tips are at the same position relative to the burner housing, preferably uniform in length. However, the flame tips could vary, for example, depending on non-uniform ribbon configurations or non-uniform gas flow into the ribbons. For illustration purposes, the plurality of flames is represented by the one flame 624. Distance “D” represents the distance between the face 540 of the burner 536 and the first side 572 of the film 570. Distance “E” represents the distance between the ribbons 542 of the burner 536 and the face 540 of the burner 536.

In FIG. 9, distance “C1” represents the relative distance between distance A and distance B, if they were subtracted A-B. This distance C1 will be a positive distance because the flame 624 is positioned away from the backing roll 514 and thus, does not impinge the film 570 on the backing roll 514, and is defined as an “unimpinged flame.” In this position, the flame may be easily measured in free space by one skilled in the art, and is an uninterrupted flame. In contrast, FIG. 10 illustrates the burner positioned much closer to the film 570 on the backing roll 514, such that the tip 626 of the flame 624 actually impinges the film 570 on the support surface 515 of the backing roll 514. In this position, “C2” represents distance A subtracted from distance B, and will necessarily be a negative number. Preferably, distance A subtracted from distance B is greater than a negative 2 mm. Perforated films can be produced at higher speeds with a C2 distance of large negative numbers, while still maintaining film quality.

Additional disclosure relating to flame perforation of films may be found in U.S. Pat. App. Pub. Nos. 2004/0070100 A1 and 2005/0073070, incorporated herein by reference.

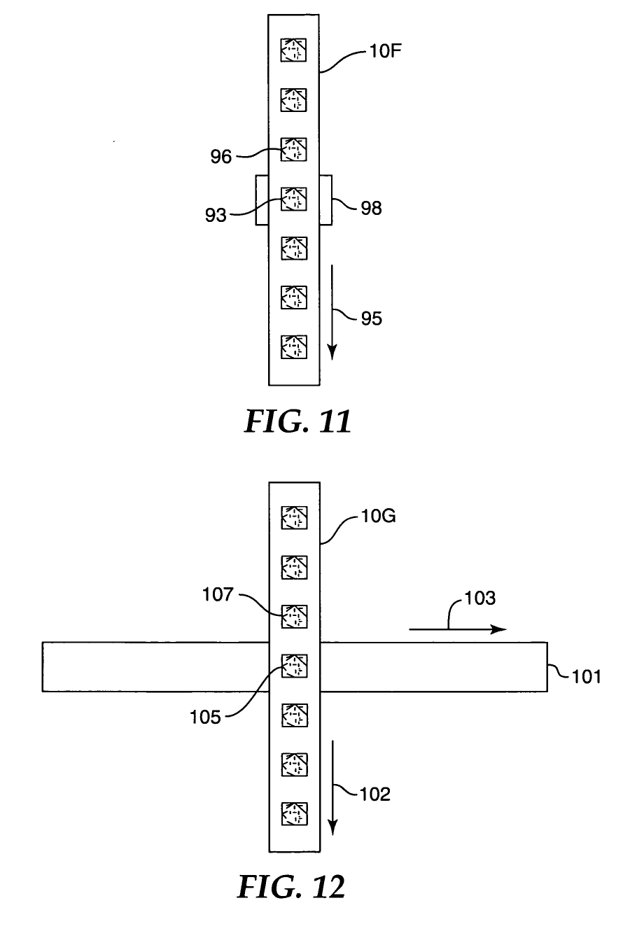

The aperture mask of the present disclosure may be used for patterned deposition of materials to make an electronic circuit element. FIGS. 11 and 12 are simplified illustrations of in-line aperture mask deposition techniques. In FIG. 11, a web of polymeric film 10F formed with deposition mask patterns 96 and 93 travels past a deposition substrate 98. A first pattern 93 in the web of polymeric film 10F can be aligned with deposition substrate 98, and a deposition process can be performed to deposit material on deposition substrate 98 according to the first pattern 93. Then, the web of polymeric film 10F can be moved (as indicated by arrow 95) such that the a second pattern 96 aligns with the deposition substrate 98, and a second deposition process can be performed. The process can be repeated for any number of patterns formed in the web of polymeric film 10F. The deposition mask pattern of polymeric film 10F can be reused by repeating the above steps on a different deposition substrate or a different portion of the same substrate.

FIG. 12 illustrates another in-line aperture mask deposition technique. In the example of FIG. 12, the deposition substrate 101 may comprise a web. In other words, both the aperture mask 10G and the deposition substrate 101 may comprise webs, possibly made from polymeric material. Alternatively, deposition substrate web 101 may comprise a conveyance web carrying a series of discrete substrates. A first pattern 105 in the aperture mask web 10G can be aligned with deposition substrate web 101 for a first deposition process. Then, either or both the aperture mask web 10G and the deposition substrate web 101 can be moved (as indicated by arrows 102 and 103) such that a second pattern 107 in aperture mask web 10G is aligned with the deposition substrate web 101 and a second deposition process performed. If each of the aperture mask patterns in the aperture mask web 10G are substantially the same, the technique illustrated in FIG. 12 can be used to deposit similar deposition layers in a number of sequential locations along the deposition substrate web 101.

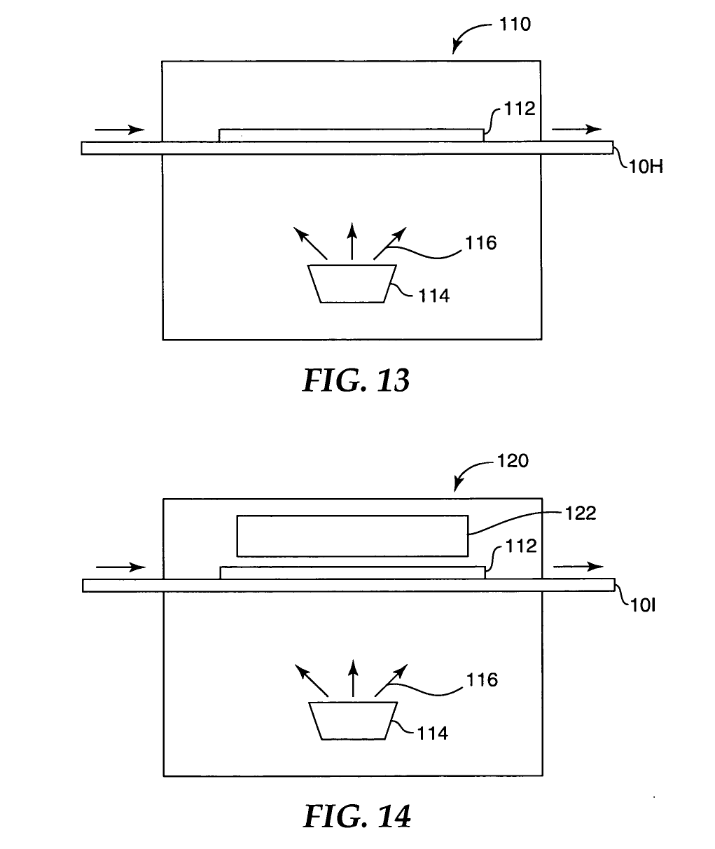

FIG. 13 is a simplified block diagram of a deposition station that can use an aperture mask web in a deposition process according to the invention. In particular, deposition station 110 can be constructed to perform a vapor deposition process in which material is vaporized and deposited on a deposition substrate through an aperture mask. The deposited material may be any material including semiconductor material, dielectric material, or conductive material used to form a variety of elements within an integrated circuit. For example, organic or inorganic materials may be deposited. In some cases, both organic and inorganic materials can be deposited to create a circuit. In another example, amorphous silicon may be deposited. Deposition of amorphous silicon typically requires high temperatures greater than approximately 200 degrees Celsius. Some embodiments of polymeric webs described herein can withstand these high temperatures, thus allowing amorphous silicon to be deposited and patterned to create integrated circuits or integrated circuit elements. In another example, pentacene-based materials can be deposited. In yet another example, OLED materials can be deposited.

A flexible web 10H formed with aperture mask patterns passes through deposition station 110 such that the mask can be placed in proximity with a deposition substrate 112. Deposition substrate 112 may comprise any of a variety of materials depending on the desired circuit to be created. For example, deposition substrate 112 may comprise a flexible material, such as a flexible polymer, e.g., polyimide or polyester, possibly forming a web. Additionally, if the desired circuit is a circuit of transistors for an electronic display such as a liquid crystal display, deposition substrate 112 may comprise the backplane of the electronic display. Any deposition substrates such as glass substrates, silicon substrates, rigid plastic substrates, metal foils coated with an insulating layer, or the like, could also be used. In any case, the deposition substrate may or may not include previously formed features.

Deposition station 110 is typically a vacuum chamber. After a pattern in aperture mask web 10H is secured in proximity to deposition substrate 112, material 116 is vaporized by deposition unit 114. For example, deposition unit 114 may include a boat of material that is heated to vaporize the material. The vaporized material 116 deposits on deposition substrate 112 through the deposition apertures of aperture mask web 10H to define at least a portion of a circuit layer on deposition substrate 112. Upon deposition, material 116 forms a deposition pattern defined by the pattern in aperture mask web 10H. Aperture mask web 10H may include apertures and gaps that are sufficiently small to facilitate the creation of small circuit elements using the deposition process as described above. Additionally, the pattern of deposition apertures in aperture mask web 10H may have a large dimension as mentioned above. Other suitable deposition techniques include e-beam evaporation, various forms of sputtering, and pulsed laser deposition.

However, when patterns in the aperture mask web 10H are made sufficiently large, for example, to include a pattern that has large dimensions, a sag problem may arise. In particular, when aperture mask web 10H is placed in proximity to deposition substrate 112, aperture mask web 10H may sag as a result of gravitational pull. This problem is most apparent when the aperture mask 10H is positioned underneath deposition substrate as shown in FIG. 10. Moreover, the sag problem compounds as the dimensions of aperture mask web 10H are made larger and larger.

The invention may implement one of a variety of techniques to address the sag problem or otherwise control sag in aperture masks during a deposition process. For example, the web of aperture masks may define a first side that can removably adhere to a surface of a deposition substrate to facilitate intimate contact between the aperture mask and the deposition substrate during the deposition process. In this manner, sag can be controlled or avoided. In particular, a first side of flexible aperture mask 10H may include a pressure sensitive adhesive. In that case, the first side can removably adhere to deposition substrate 112 via the pressure sensitive adhesive, and can then be removed after the deposition process, or be removed and repositioned as desired.

Another way to control sag is to use magnetic force. For example, referring again to FIG. 1, aperture mask 10A may comprise both a polymer and magnetic material. The magnetic material may be coated or laminated on the polymer, or can be impregnated into the polymer. For example, magnetic particles may be dispersed within a polymeric material used to form aperture mask 10A. When a magnetic force is used, a magnetic field can be applied within a deposition station to attract or repel the magnetic material in a manner that controls sag in aperture mask 10A.

For example, as illustrated in FIG. 14, a deposition station 120 may include magnetic structure 122. Aperture mask 101 may be an aperture mask web that includes a magnetic material. Magnetic structure 122 may attract aperture mask web 110 so as to reduce, eliminate, or otherwise control sag in aperture mask web 101. Alternatively, magnetic structure 122 may be positioned such that sag is controlled by repelling the magnetic material within aperture mask web 101. In that case, magnetic structure 122 would be positioned on the side of aperture mask 110 opposite deposition substrate 112. For example, magnetic structure 122 can be realized by an array of permanent magnets or electromagnets.

Another way to control sag is the use of electrostatics. In that case, aperture mask 10A may comprise a web of polymeric film that is electrostatically coated. Although magnetic structure 122 (FIG. 14) may not be necessary if an electrostatic coating is used to control sag, it may be helpful in some cases where electrostatics are used. A charge may be applied to the aperture mask web, the deposition substrate web, or both to promote electrostatic attraction in a manner that promotes a sag reduction.

Still another way to control sag is to stretch the aperture mask. In that case, a stretching mechanism can be implemented to stretch the aperture mask by an amount sufficient to reduce, eliminate, or otherwise control sag. As the mask is stretched tightly, sag is reduced. In that case, the aperture mask may need to have an acceptable coefficient of elasticity. As described in greater detail below, stretching in a cross-web direction, a down-web direction, or both can be used to reduce sag and to align the aperture mask. In order to allow ease of alignment using stretching, the aperture mask can allow elastic stretching without damage. The amount of stretching in one or more directions may be greater than 0.1 percent, or even greater than 1 percent. Additionally, if the deposition substrate is a web of material, it too can be stretched for sag reduction and/or alignment purposes. Also, the aperture mask web, the deposition substrate web, or both may include distortion minimizing features, such as perforations, reduced thickness areas, slits, or similar features, which facilitate more uniform stretching. The slits can be added near the edges of the patterned regions of the webs and may provide better control of alignment and more uniform stretching when the webs are stretched. The slits may be formed to extend in directions parallel to the directions that the webs are stretched.

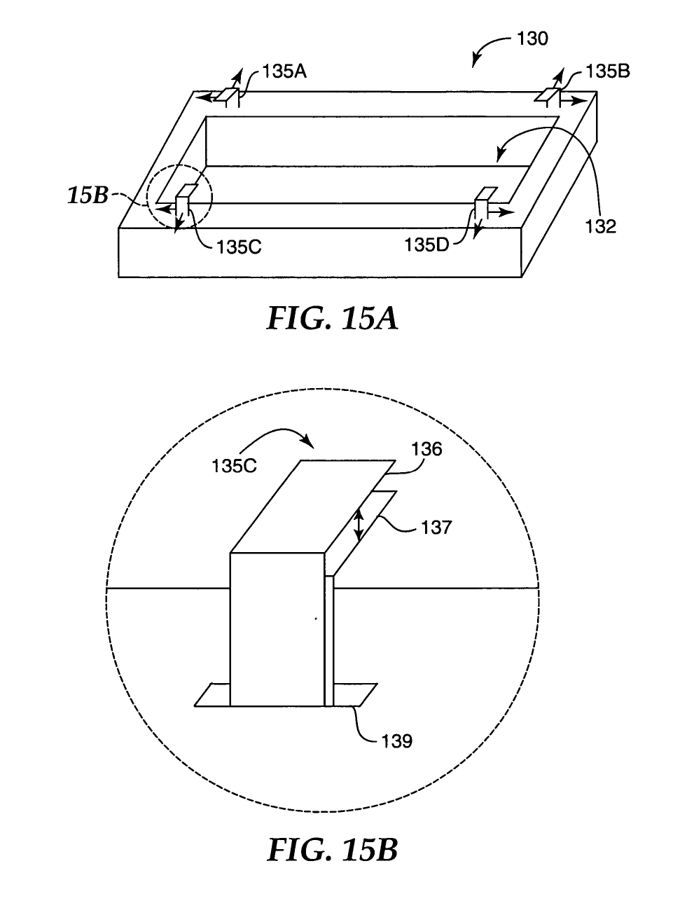

FIG. 15a is a perspective view of an exemplary stretching apparatus for stretching aperture mask webs in accordance with the invention. Stretching can be performed in a down-web direction, a cross-web direction, or both the cross and down-web directions. Stretching unit 130 may include a relatively large deposition hole 132. An aperture mask can cover deposition hole 132 and a deposition substrate can be placed in proximity with the aperture mask. Material can be vaporized up through deposition hole 132, and deposited on the deposition substrate according to the pattern defined in the aperture mask.

Stretching apparatus 130 may include a number of stretching mechanisms 135A, 135B, 135C and 135D. Each stretching mechanism 135 may protrude up through a stretching mechanism hole 139 shown in FIG. 15b. In one specific example, each stretching mechanism 135 includes a top clamp portion 136 and a bottom clamp portion 137 that can clamp together upon an aperture mask. The aperture mask can then be stretched by moving stretching mechanisms 135 away from one another as they clamp the aperture mask. The movement of the stretching mechanisms can define whether the aperture mask is stretched in a down-web direction, a cross-web direction, or both. Stretching mechanisms 135 may move along one or more axes.

Stretching mechanisms 135 are illustrated as protruding from the top of stretching apparatus 130, but could alternatively protrude from the bottom of stretching apparatus 130. Particularly, if stretching apparatus 130 is used to control sag in an aperture mask, the stretching mechanisms would typically protrude from the bottom of stretching apparatus 130. Alternative methods of stretching the aperture mask could also be used either to control sag in the aperture mask or to properly align the aperture mask for the deposition process. A similar stretching mechanism could also be used to stretch a deposition substrate web.

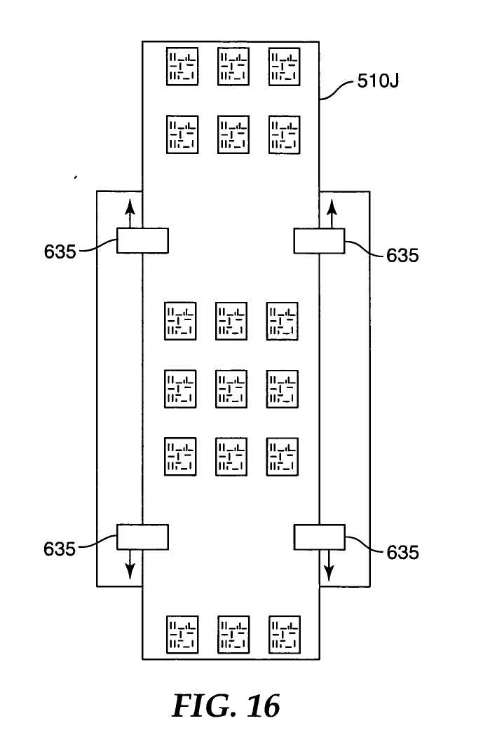

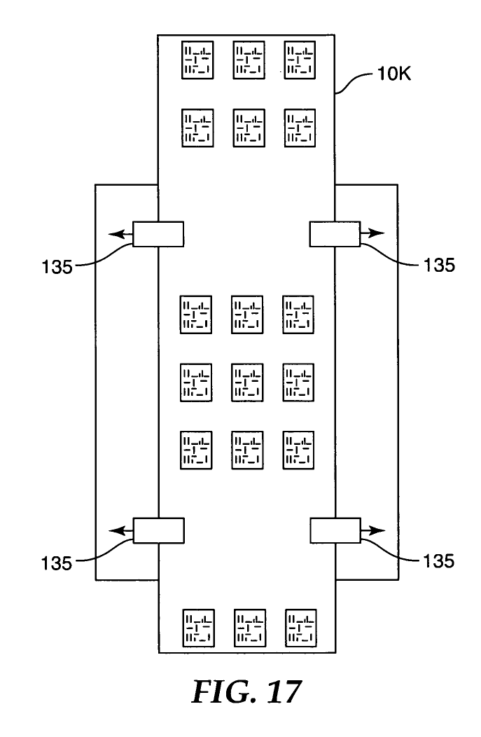

FIGS. 16 and 17 are top views of stretching apparatuses illustrating the stretching of aperture masks in a down-web direction (FIG. 16) and a cross-web direction (FIG. 17). As illustrated in FIG. 16, stretching mechanisms 135 clamp upon aperture mask web 10J, and then move in a direction indicated by the arrows to stretch aperture mask web 10J in a down-web direction. Any number of stretching mechanisms 135 may be used. In FIG. 17, stretching mechanisms 135 stretch aperture mask web 10K in a cross-web direction as indicated by the arrows. Additionally, stretching in both a cross-web direction and a down-web direction can be implemented. Indeed, stretching along any of one or more defined axes can be implemented.

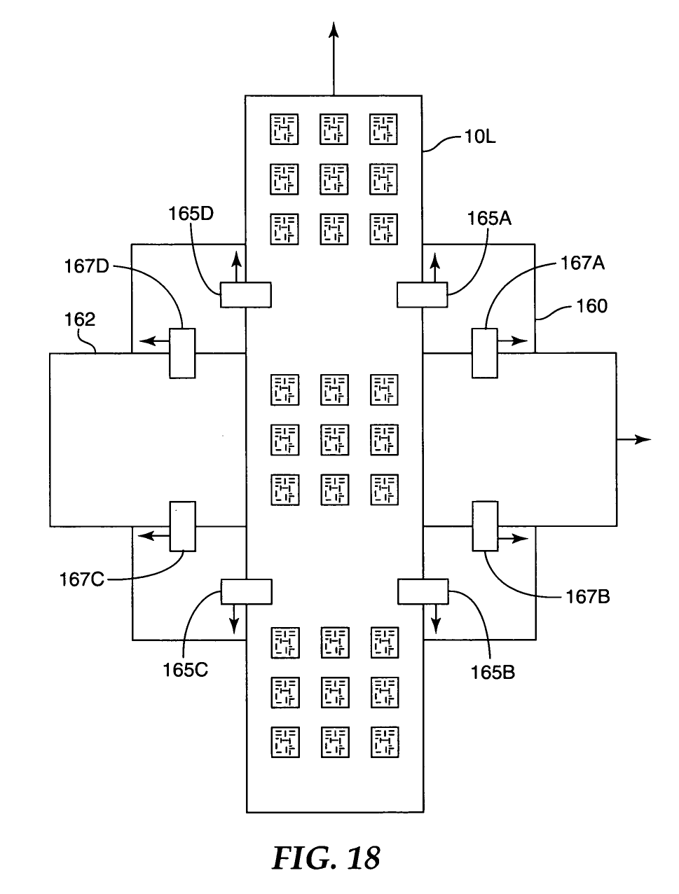

FIG. 18 is a top view of a stretching apparatus 160 that can be used to stretch both an aperture mask web 10L and a deposition substrate web 162. In particular, stretching apparatus 160 includes a first set of stretching mechanisms 165A-165D that clamp upon aperture mask web 10L to stretch aperture mask web 10L. Also, stretching apparatus 160 includes a second set of stretching mechanisms (167A-167D) that clamp upon deposition substrate web 162 to stretch deposition substrate web 162. The stretching can reduce sag in the webs 10L and 162, and can also be used to achieve precise alignment of aperture mask web 10L and deposition substrate web 162. Although the arrows illustrate stretching in a down-web direction, stretching in a cross-web direction or both a down-web and a cross-web direction may also be implemented according to the invention.

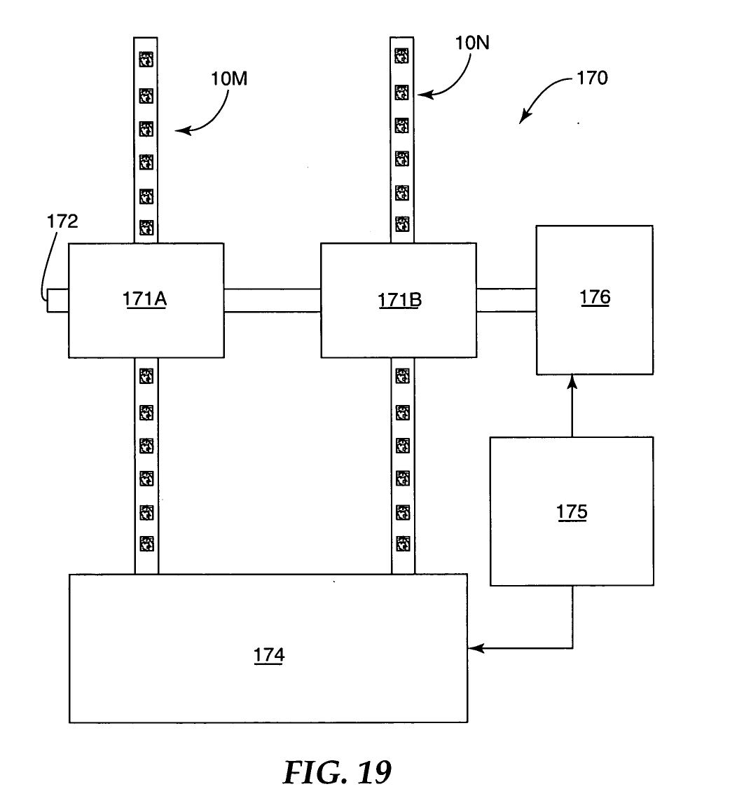

FIG. 19 is a block diagram of an in-line deposition system 170 according to an embodiment of the invention. As shown, in-line deposition system 170 includes a number of deposition stations 171A-171B (hereafter deposition stations 171). Deposition stations 171 deposit material on a deposition substrate web at substantially the same time. Then, after a deposition, the deposition substrate 172 moves such that subsequent depositions can be performed. Each deposition station also has an aperture mask web that feeds in a direction such that it crosses the deposition substrate. Typically, the aperture mask web feeds in a direction perpendicular to the direction of travel of the deposition substrate. For example, aperture mask web 10M may be used by deposition station 171A, and aperture mask web 10N may be used by deposition station 171B. Each aperture mask web 10 may include one or more of the features outlined above. Although illustrated as including two deposition stations, any number of deposition stations can be implemented in an in-line system according to the invention. Multiple deposition substrates may also pass through one or more of the deposition stations.

Deposition system 170 may include drive mechanisms 174 and 176 to move the aperture mask webs 10 and the deposition substrate 172, respectively. For example, each drive mechanism 174, 176 may implement one or more magnetic clutch mechanisms to drive the webs and provide a desired amount of tension. Control unit 175 can be coupled to drive mechanisms 174 and 176 to control the movement of the webs in deposition system 170. The system may also include one or more temperature control units to control temperature within the system. For example, a temperature control unit can be used to control the temperature of the deposition substrate within one or more of the deposition stations. The temperature control may ensure that the temperature of the deposition substrate does not exceed 250 degrees Celsius, or does not exceed 125 degrees Celsius.

Additionally, control unit 175 may be coupled to the different deposition stations 171 to control alignment of the aperture mask webs 10 and the deposition substrate web 172. In that case, optical sensors and/or motorized micrometers may be implemented with stretching apparatuses in deposition stations 171 to sense and control alignment during the deposition processes. In this manner, the system can be completely automated to reduce human error and increase throughput. After all of the desired layers have been deposited on deposition substrate web 172, the deposition substrate web 172 can be cut or otherwise separated into a number of circuits. The system can be particularly useful in creating low cost integrated circuits such as radio frequency identification (RFID) circuits or displays including OLED displays.

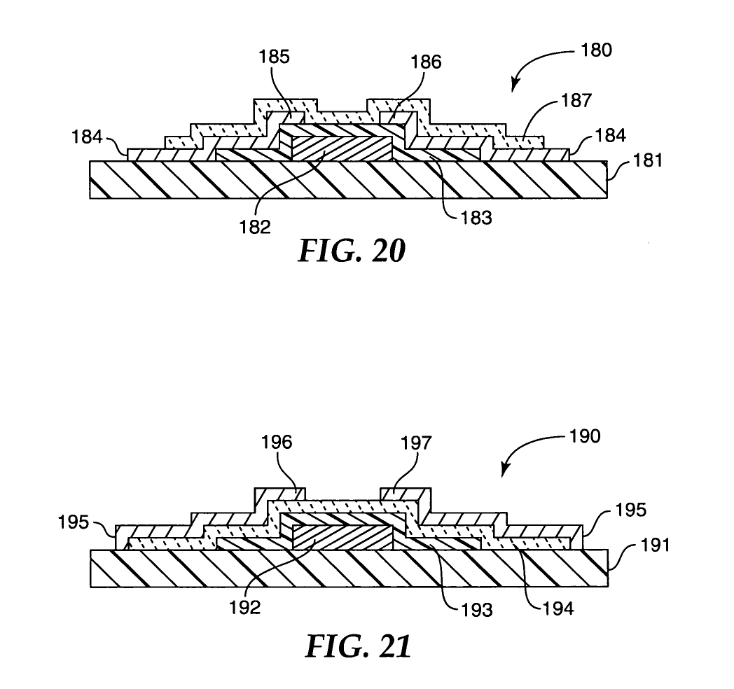

FIGS. 20 and 21 are cross-sectional views of exemplary thin film transistors that can be created according to the invention. In accordance with the invention, thin film transistors 180 and 190 can be created without using photolithography in an additive or subtractive process. Instead, thin film transistors 180 and 190 can be created solely using aperture mask deposition techniques as described herein. Alternatively, one or more bottom layers may be photolithographically patterned in an additive or subtractive process, with at least two of the top most layers being formed by the aperture mask deposition techniques described herein. Importantly, the aperture mask deposition techniques achieve sufficiently small circuit features in the thin film transistors. Advantageously, if an organic semiconductor is used, the invention can facilitate the creation of thin film transistors in which the organic semiconductor is not the top-most layer of the circuit. Rather, in the absence of photolithography, electrode patterns may be formed over the organic semiconductor material. This advantage of aperture mask 10 can be exploited while at the same time achieving acceptable sizes of the circuit elements, and in some cases, improved device performance.

An additional advantage of this invention is that an aperture mask may be used to deposit a patterned active layer which may enhance device performance, particularly in cases where the active layer comprises an organic semiconductor, for which conventional patterning processes are incompatible. In general, the semiconductor may be amorphous (e.g., amorphous silicon) or polycrystalline (e.g., pentacene).

Thin film transistors are commonly implemented in a variety of different circuits, including, for example, RFID circuits and other low cost circuits. In addition, thin film transistors can be used as control elements for liquid crystal display pixels, or other flat panel display pixels such as organic light emitting diodes. Many other applications for thin film transistors also exist.

As shown in FIG. 20, thin film transistor 180 is formed on a deposition substrate 181. Thin film transistor 180 represents one embodiment of a transistor in which all of the layers are deposited using an aperture mask and none of the layers are formed using etching or lithography techniques. The aperture mask deposition techniques described herein can enable the creation of thin film transistor 180 in which a distance between the electrodes is less than approximately 1000 microns, less than approximately 500 microns, less than approximately 250 microns, or even less than approximately 200 microns, while at the same time avoiding conventional etching or photolithographic processes.

In particular, thin film transistor 180 may include a first deposited conductive layer 182 formed over deposition substrate 181. A deposited dielectric layer 183 is formed over first conductive layer 182. A second deposited conductive layer 184 defining source electrode 185 and drain electrode 186 is formed over deposited dielectric layer 183. A deposited active layer 187, such as a deposited semiconductor layer, or a deposited organic semiconductor layer is formed over second deposited conductive layer 184.

Aperture mask deposition techniques using an in-line deposition system, represent one exemplary method of creating thin film transistor 180. In that case, each layer of thin film transistor 180 may be defined by one or more deposition apertures in a flexible aperture mask web 10. Alternatively, one or more of the layers of the thin film transistor may be defined by a number of different patterns in aperture mask web 10. In that case, stitching techniques, as mentioned above, may be used.

By forming deposition apertures 14 in aperture mask webs 10 to be sufficiently small, one or more features of thin film transistor 180 can be made less than approximately 1000 microns, less than approximately 500 microns, less than 250 microns, or even less than 200 microns. Moreover, by forming a gap in aperture mask webs 10 to be sufficiently small, other features such as the distance between source electrode 185 and drain electrode 186 can be made less than approximately 1000 microns, less than approximately 500 microns, less than 250 microns, or even less than 200 microns. In that case, a single mask pattern may be used to deposit second conductive layer 184, with each of the two electrodes 185, 186 being defined by deposition apertures separated by a sufficiently small gap, such as a gap less than approximately 1000 microns, less than approximately 500 microns, less than 250 microns, or even less than 200 microns. In this manner, the size of thin film transistor 180 can be reduced, enabling fabrication of smaller, higher density circuitry while improving the performance of thin film transistor 180. Additionally, a circuit comprising two or more transistors, like that illustrated in FIG. 20 can be formed by an aperture mask web having two deposition apertures of a pattern separated by a large distance, as illustrated in FIGS. 3 and 4.

FIG. 21 illustrates another embodiment of a thin film transistor 190. In particular, thin film transistor 190 includes a first deposited conductive layer 192 formed over deposition substrate 191. A deposited dielectric layer 193 is formed over first conductive layer 192. A deposited active layer 194, such as a deposited semiconductor layer, or a deposited organic semiconductor layer is formed over deposited dielectric layer 193. A second deposited conductive layer 195 defining source electrode 196 and drain electrode 197 is formed over deposited active layer 194.

Again, by forming deposition apertures 14 in aperture mask webs 10 to be sufficiently small, one or more features of thin film transistor 190 can have widths on the order of those discussed herein. Also, by forming a gap between apertures in aperture mask webs 10 to be sufficiently small, the distance between source electrode 196 and drain electrode 197 can be on the order of the gap sizes discussed herein. In that case, a single mask pattern may be used to deposit second conductive layer 195, with each of the two electrodes 196, 197 being defined by deposition apertures separated by a sufficiently small gap. In this manner, the size of thin film transistor 190 can be reduced, and the performance of thin film transistor 190 improved.

Thin film transistors implementing organic semiconductors generally take the form of FIG. 20 because organic semiconductors cannot be etched or lithographically patterned without damaging or degrading the performance of the organic semiconductor material. For instance, morphological changes can occur in an organic semiconductor layer upon exposure to processing solvents. For this reason, fabrication techniques in which the organic semiconductor is deposited as a top layer may be used. The configuration of FIG. 21 is advantageous because top contacts to the electrodes provide a low-resistance interface.

By forming at least the top two layers of the thin film transistor using aperture mask deposition techniques, the invention facilitates the configuration of FIG. 21, even if active layer 194 is an organic semiconductor layer. The configuration of FIG. 21 can promote growth of the organic semiconductor layer by allowing the organic semiconductor layer to be deposited over the relatively flat surface of dielectric layer 193, as opposed to being deposited over the non-continuous second conductive layer 184 as illustrated in FIG. 20. For example, if the organic semiconductor material is deposited over a non-flat surface, growth can be inhibited. Thus, to avoid inhibited organic semiconductor growth, the configuration of FIG. 21 may be desirable. In some embodiments, all of the layers may be deposited as described above. Also, the configuration of FIG. 21 is advantageous because depositing appropriate source and drain electrodes on the organic semiconductor provides low-resistance interfaces. Additionally, circuits having two or more transistors separated by a large distance can also be created, for example, using aperture mask webs like those illustrated in FIGS. 3 and 4.

The use of a quickly-made and disposable aperture mask according to the present invention enables easier recovery of deposition material accumulated on the aperture mask. Such materials may include metals, including precious metals such as gold or silver, or any other material deposited in the fabrication of an electronic circuit element. The recovery of deposition material may be accomplished with destruction of the aperture mask or other alteration of the aperture mask that may preclude reuse of the aperture mask. The recovery of deposition material may be accomplished by processes which involve partially or wholly burning the aperture mask partially or wholly melting the aperture mask, partially or wholly separating the aperture mask into pieces, e.g., by slicing, cutting, chopping, grinding, or milling, or partially or wholly dissolving the aperture mask, e.g., in solvents. The use of a quickly-made and disposable aperture mask according to the present invention enables a process where cleaning of the aperture mask is avoided by frequent replacement of the aperture mask.

In a further embodiment, the aperture mask according to the present disclosure may be used in roll-to-roll processes and apparatus therefor or continuous processes and apparatus therefor as taught in U.S. patent application Ser. No. 11/179,418, the disclosure of which is incorporated herein by reference.

A number of embodiments of the invention have been described. For example, a number of different structural components and different aperture mask deposition techniques have been described for realizing an in-line deposition system. The deposition techniques can be used to create various circuits solely using deposition, avoiding any chemical etching processes or photolithography, which is particularly useful when organic semiconductors are involved. Moreover, the system can be automated to reduce human error and increase throughput. Nevertheless, it is understood that various modifications can be made without departing from the spirit and scope of the invention. For example, although some aspects of the invention have been described for use in a thermal vapor deposition process, the techniques and structural apparatuses described herein could be used with any deposition process including sputtering, thermal evaporation, electron beam evaporation and pulsed laser deposition. Thus, these other embodiments are within the scope of the following claims.

We claim:

1. An aperture mask comprising:
an elongated web of flexible film; and
at least one deposition mask pattern formed in the film,
wherein the deposition mask pattern defines deposition apertures that extend through the film that define at least a portion of one or more electronic circuit elements, and
wherein deposition apertures are bounded by a rim, the rim being a portion of the mask which has a thickness greater than an average thickness for the mask.

2. The aperture mask of claim 1, wherein the aperture mask comprises a plurality of independent deposition mask patterns.

3. The aperture mask of claim 2, wherein each deposition mask pattern is substantially the same.

4. The aperture mask of claim 1, wherein the web of film is sufficiently flexible such that it can be wound to form a roll.

5. The aperture mask of claim 1, wherein the web of film is stretchable such that it can be stretched in at least a down-web direction.

6. The aperture mask of claim 1, wherein the web of film is stretchable in at least a cross-web direction.

7. The aperture mask of claim 1, wherein the web of film comprises a polymeric film.

8. The aperture mask of claim 1, wherein the web of film comprises a polyimide film.

9. The aperture mask of claim 1, wherein the web of film comprises a polyester film.

10. The aperture mask of claim 1, wherein at least one deposition aperture has a smallest diameter of less than approximately 1000 microns.

11. The aperture mask of claim 1, wherein at least one deposition aperture has a smallest diameter of less than approximately 250 microns.

12. A method of making an aperture mask comprising:
an elongated web of flexible film; and
a deposition mask pattern formed in the film,
wherein the deposition mask pattern defines deposition apertures that extend through the film that define at least a portion of one or more electronic circuit elements;
the method comprising the steps of:
providing a support surface, wherein the support surface includes a plurality of lowered portions;
providing a burner, wherein the burner supports a flame, and wherein the flame includes a flame tip opposite the burner;
contacting at least a portion of an elongated web of flexible film against the support surface; and
heating the film with a flame from a burner to create apertures in the film in the areas covering the plurality of lowered portions.

13. The method according to claim 12, wherein the support surface is cooled to a temperature lower than 120° F. (29° C.); and additionally comprising the steps of:
contacting the first side of the film with a heated surface, wherein the heated surface is greater than 165° F. (74° C.); and subsequently
removing the heated surface from the first side of the film prior to heating the film with a flame from a burner to create apertures in the film in the areas covering the plurality of lowered portions.

14. The method according to claim 12, additionally comprising the step of:
positioning the burner such that the distance between an unimpinged flame tip of the flame and the burner is at least one-third greater than the distance between the film and the burner.

15. The method according to claim 14, wherein the positioning step includes positioning the burner such that the distance between the unimpinged flame tip of the flame and the burner is at least 2 millimeters greater than the distance between the film and the burner.

16. The method according to claim 12, additionally comprising the step of:
positioning the burner such that the angle measured between the burner and the nip roll is less than 45°, wherein a vertex of the angle is positioned at an axis of the backing roll.

17. The method according to claim 12, wherein the aperture mask comprises a plurality of independent deposition mask patterns.

18. The method according to claim 12, wherein the web of film is sufficiently flexible such that it can be wound to form a roll.

19. The method according to claim 12, wherein the web of film comprises a polymeric film.

20. The method according to claim 12, wherein the web of film comprises a polyimide film.

21. The method according to claim 12, wherein the web of film comprises a polyester film.

22. A method of making an electronic circuit element, comprising the steps of:
providing a support surface, wherein the support surface includes a plurality of lowered portions;
providing a burner, wherein the burner supports a flame, and wherein the flame includes a flame tip opposite the burner;
contacting at least a portion of an elongated web of flexible film against the support surface;
heating the film with a flame from a burner to create apertures in the film in the areas covering the plurality of lowered portions, thereby making an aperture mask;
providing a first web of film;
positioning the aperture mask and first web of film in proximity to each other; and
depositing a deposition material on the first web of film through the apertures in the aperture mask to create at least a portion of one or more electronic circuit elements.

23. The method according to claim 22, additionally comprising the step of recovering deposition material accumulated on the aperture mask by a method which precludes reuse of the aperture mask.

24. The method according to claim 22, additionally comprising the step of recovering deposition material accumulated on the aperture mask by a method which including a step selected from the group consisting of: partially or wholly burning the aperture mask, partially or wholly melting the aperture mask, partially or wholly dividing the aperture mask into pieces, and partially or wholly dissolving the aperture mask.

25. The method according to claim 22, wherein the support surface is cooled to a temperature lower than 120° F. (29° C.); and additionally comprising the steps of:
contacting the first side of the film with a heated surface, wherein the heated surface is greater than 165° F. (74° C.); and subsequently
removing the heated surface from the first side of the film prior to heating the film with a flame from a burner to create apertures in the film in the areas covering the plurality of lowered portions.

26. The method according to claim 22, additionally comprising the step of:
positioning the burner such that the distance between an unimpinged flame tip of the flame and the burner is at least one-third greater than the distance between the film and the burner.

27. The method according to claim 26, wherein the positioning step includes positioning the burner such that the distance between the unimpinged flame tip of the flame and the burner is at least 2 millimeters greater than the distance between the film and the burner.

28. The method according to claim 22, additionally comprising the step of:
positioning the burner such that the angle measured between the burner and the nip roll is less than 45°, wherein a vertex of the angle is positioned at an axis of the backing roll.

29. The method according to claim 22, wherein the aperture mask comprises a plurality of independent deposition mask patterns.

30. The method according to claim 22, wherein the web of film is sufficiently flexible such that it can be wound to form a roll.

31. The method according to claim 22, wherein the web of film comprises a polymeric film.

32. The method according to claim 22, wherein the web of film comprises a polyimide film.

33. The method according to claim 22, wherein the web of film comprises a polyester film.

34. An apparatus for continuously depositing a pattern of material on a substrate, comprising:
a substrate delivery roller from which the substrate is delivered;
a first substrate receiving roller upon which the substrate is received such that the substrate extends from the substrate delivery roller to the substrate receiving roller, the substrate continuously passing from the substrate delivery roller to the substrate receiving roller;
a first mask containing apertures defining a first pattern, comprising:
an elongated web of flexible film; and
at least one deposition mask pattern formed in the film,
wherein the deposition mask pattern defines deposition apertures that extend through the film that define at least a portion of one or more electronic circuit elements, and
wherein deposition apertures are bounded by a rim, the rim being a portion of the mask which has a thickness greater than an average thickness for the mask;
a first mask delivery roller from which the first mask is delivered;
a first mask receiving roller upon which the first mask is received such that the mask extends from the mask delivery roller to the mask receiving roller, the first mask continuously passing from the first mask delivery roller to the first mask receiving roller;
a first drum upon which the substrate and first polymeric mask come into contact over a portion of the circumference of the first drum between delivery from the substrate and mask delivery roller and reception onto the substrate and mask receiving rollers, the first drum continuously rotating; and
a first deposition source positioned to continuously direct first deposition material toward the portion of the first mask that is over the portion of the circumference of the first drum such that at least a portion of the first deposition material passes through the apertures of the first mask to continuously deposit the first pattern of the first material on the substrate.

35. The apparatus of claim 34, further comprising:
a first substrate elongation control system that maintains a pre-determined elongation of the substrate in the direction of delivery from the substrate delivery roller to the first drum as the substrate comes into contact over a portion of the circumference of the first drum; and
a first mask elongation control system that maintains a pre-determined elongation of the first mask in the direction of delivery from the first mask delivery roller to the first drum as the first mask comes into contact over a portion of the circumference of the first drum.

36. The apparatus of claim 34, further comprising:
a first substrate transverse position control system including a web guide that adjusts the transverse position of the substrate to a pre-determined transverse location on the first drum; and
a first mask transverse position control system including a web guide that adjusts the transverse position of the first mask to a pre-determined transverse location on the first drum.

37. The apparatus of claim 34, wherein the substrate is in direct contact with the first drum over the portion of the circumference of the first drum, wherein the first mask is in direct contact with the substrate over the portion of the circumference of the first drum, and wherein the first deposition source is positioned at a location exterior to the first drum such that the first mask is located between the substrate and the first deposition source.

38. The apparatus of claim 34, wherein the first drum includes apertures spaced about the circumference, wherein the first mask is in direct contact with the first drum and spans the apertures over the portion of the circumference of the first drum, wherein the substrate is in direct contact with the first mask over the portion of the circumference of the first drum, and wherein the first deposition source is positioned on the interior of the first drum such that the first mask is located between the substrate and the first deposition source.

39. The apparatus of claim 34, further comprising:
a second mask containing apertures defining a second pattern, comprising:
an elongated web of flexible film; and
at least one second deposition mask pattern formed in the film,
wherein the second deposition mask pattern defines second deposition apertures that extend through the film that define at least a second portion of one or more electronic circuit elements, and
wherein second deposition apertures are bounded by a rim, the rim being a portion of the mask which has a thickness greater than an average thickness for the mask;
a second mask delivery roller from which the second mask is delivered;
a second mask receiving roller upon which the second mask is received such that the second polymeric mask extends from the mask delivery roller to the mask receiving roller, the second mask continuously passing from the second mask delivery roller to the second mask receiving roller;
a second substrate receiving roller upon which the substrate is received, the substrate continuously passing from the first substrate receiving roller to the second substrate receiving roller;
a second drum upon which the substrate and the second mask come into contact over a portion of the circumference of the second drum, the second drum receiving the substrate between the substrate receiving roller and the second substrate receiving roller, the second drum continuously rotating; and
a second deposition source positioned to continuously direct second deposition material toward a portion of the second mask that is over the portion of the circumference of the second drum such that at least a portion of the second deposition material passes through the apertures of the second mask to deposit the second pattern of the second material onto the substrate.

40. A method of continuously depositing material, comprising:
continuously delivering a substrate from a substrate delivery roller while continuously receiving the substrate onto a substrate receiving roller, wherein the substrate passes over a portion of a circumference of a first drum when between the substrate delivery roller and the substrate receiving roller;
while continuously delivering and receiving the substrate, continuously delivering a first mask from a first mask delivery roller while continuously receiving the first mask onto a first mask receiving roller, wherein the first mask passes over a portion of a circumference of the first drum when between the first mask delivery roller and the first mask receiving roller; wherein the first mask comprises an elongated web of flexible film and at least one deposition mask pattern formed in the film, wherein the deposition mask pattern defines deposition apertures that extend through the film that define at least a portion of one or more electronic circuit elements, and wherein deposition apertures are bounded by a rim, the rim being a portion of the mask which has a thickness greater than an average thickness for the mask;
while continuously delivering and receiving the substrate and the first mask, continuously directing a first deposition material from a first deposition source toward a portion of the first mask that is over the portion of the circumference of the first drum such that the first pattern of first material is deposited on the substrate.
